(19) United States
(12) Patent Application Publication
(10) Pub. No.: US 2026/0237412 A1
(43) Pub. Date: Aug. 13, 2026

(54) STORAGE CIRCUIT

(71) Applicant: Arm Limited, Cambridge (GB)

(72) Inventors: Andy Wangkun CHEN, Austin, TX (US); Yew Keong CHONG, Austin, TX (US); Sriram THYAGARAJAN, Austin, TX (US); Abhishek Kumar SINGH, Bangalore (IN)

(21) Appl. No.: 19/049,071

(22) Filed: Feb. 10, 2025

(51) Int. Cl. G11C 7/10

(52) U.S. Cl. CPC G11C 7/1042; G11C 7/1012; G11C 7/1063

(57) ABSTRACT

A storage circuit, a method, a device and a non-transitory computer-readable medium. The storage circuit includes a first storage circuit instance having a first physical storage circuit, a second storage circuit instance having one or more pairs of second physical storage circuits; and a selection circuit to select, for a given output of the storage circuit system, an output from the first storage circuit instance or an output from the second storage circuit instance.

### FIELD

The present disclosure relates to an improved storage circuit.

### BACKGROUND

Conventionally, storage circuits (i.e. memory), are utilized to store data in the form of bits in bitcells which can be written to and read from the memory as required. Memory is often defined by a logical instance having a required size which is typically implemented, or formed, by a series (also referred to as copies) of smaller physical instances of the same size that combine to provide the required logical instance size.

For example, a memory having a logical instance size requirement of 6 k×592 may be implemented by 8 copy of a physical instance having a physical size of 6 k×74. If the requirement is for 4 copy of the logical instance then that will require 32 copy of the physical instance.

Each physical instance has an associated physical area on a chip and as such, an increasing logical instance size will require an increasing number (e.g. copies) of physical instances which is challenging to accommodate on a chip with a power, performance and area (PPA) requirement, especially in smaller, e.g. mobile, devices.

The Applicants have realised that the conventional approach is not area efficient, and the present disclosure seeks to address, at least in part, the disadvantages and drawbacks described above.

### SUMMARY

According to a first aspect of the present disclosure there is provided a storage circuit comprising: a first storage circuit instance, wherein the first storage circuit instance comprises a first physical storage circuit; a second storage circuit instance, wherein the second storage circuit instance comprises one or more pairs of second physical storage circuits; and a selection circuit, wherein the selection circuit is operable to select, for a given output of the storage circuit, an output from the first storage circuit instance or an output from the second storage circuit instance; wherein a number of outputs of the first physical storage circuit matches the number of outputs of each of the one or more pairs of second physical storage circuits.

In some embodiments, the selection circuit may be part of the first storage circuit instance or the second storage instance.

In some embodiments, the selection circuit may be separate to the first storage circuit instance and the second storage circuit instance.

In some embodiments, for each output of the storage circuit the selection circuit may be operable to perform bit interleaving of an output of the first storage circuit instance and one or more outputs of the second storage circuit instance.

In some embodiments, the bit interleaving for each output of the storage circuit may include bit interleaving an output of the first physical storage circuit of the first storage circuit instance with an alternating output of one or more pairs of the second physical storage circuits of the second storage circuit instance.

In some embodiments, a physical pitch of the first physical storage circuit and each of the two or more second physical storage circuits may be matched.

In some embodiments, the selection circuit may receive a control signal; and the selection may be based on the received control signal.

In some embodiments, one of the first physical storage circuit and the two or more second physical storage circuits may include a bank multiplexer.

In some embodiments, the selection circuit may include a bank multiplexer.

In some embodiments, the bank multiplexer may comprise a plurality of multiplexers, wherein each multiplexer of the bank multiplexer may comprise two or more selection inputs.

In some embodiments, each of the first physical storage circuit and the two or more second physical storage circuits may include a plurality of bitcell banks, an input/output circuit, and at least one latch and decoder circuit.

In some embodiments, the storage circuit may further comprise: a transition region located between adjacent physical storage circuits.

According to a second aspect of the present disclosure there is provided method of operating a storage circuit, the storage circuit comprising a first storage circuit instance, wherein the first storage circuit instance comprises a first physical storage circuit; a second storage circuit instance, wherein the second storage circuit instance comprises one or more pairs of second physical storage circuits; wherein a number of outputs of the first physical storage circuit matches the number of outputs of each of the one or more pairs of second physical storage circuits; and a selection circuit, the method comprising: selecting, by the selection circuit, for a given output of the storage circuit system, an output from the first storage circuit instance or an output from the second storage circuit instance.

In some embodiments, the method may further comprise: performing, by the selection circuit for each output of the storage circuit system, bit interleaving of an output of the first storage circuit instance and one or more outputs of the second storage circuit instance.

In some embodiments, the performing bit interleaving may further comprise: bit interleaving an output of the first physical storage circuit of the first storage circuit instance with an alternating output of the one or more pairs of second physical storage circuits of the second storage circuit instance.

In some embodiments, the method may further comprise: receiving a control signal; and wherein the selecting may be based on the received control signal.

According to a third aspect of the present disclosure there is provided a computer program product comprising computer readable executable code for implementing a method according to the second aspect.

According to a fourth aspect of the present disclosure there is provided a device comprising one or more copies of the storage circuit of the first aspect.

According to a fifth aspect of the present disclosure there is provided a non-transitory computer-readable medium storing computer-readable code for fabrication of a storage circuit comprising: a first storage circuit instance, wherein the first storage circuit instance comprises a first physical storage circuit; a second storage circuit instance, wherein the second storage circuit instance comprises one or more pairs of second physical storage circuits; and a selection circuit, wherein the selection circuit is operable to select, for a given output of the storage circuit system, an output from the first storage circuit instance or an output from the second storage circuit instance; wherein a number of outputs of the first physical storage circuit matches a number of outputs of each of the one or more pairs of second physical storage circuits.

It will be appreciated that any features described herein as being suitable for incorporation into one or more aspects or embodiments of the present disclosure are intended to be generalizable across any and all aspects and embodiments of the present disclosure. Other aspects of the present disclosure can be understood by those skilled in the art in light of the description, the claims, and the drawings of the present disclosure. The foregoing general description and the following detailed description are exemplary and explanatory only and are not restrictive of the claims.

Embodiments of the present disclosure will now be described, by way of example only, and with reference to the accompanying Figures, in which:

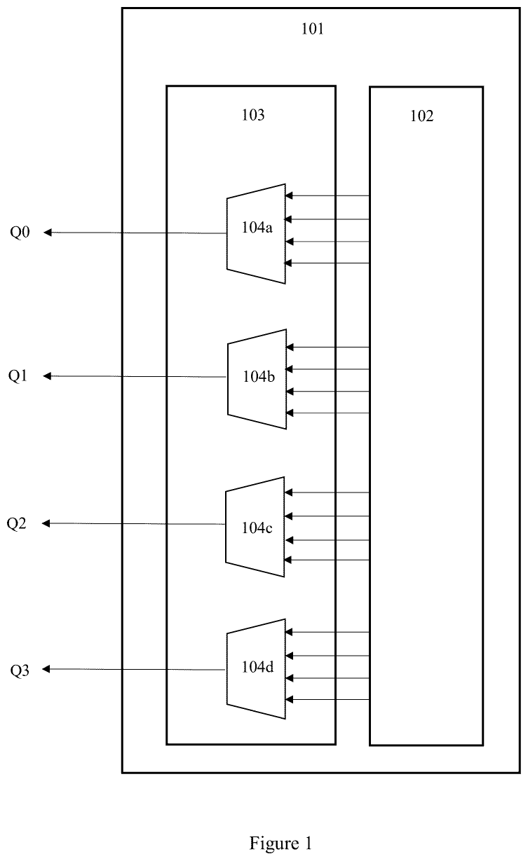

FIG. 1 schematically illustrates a storage circuit according to one or more embodiments of the present disclosure.

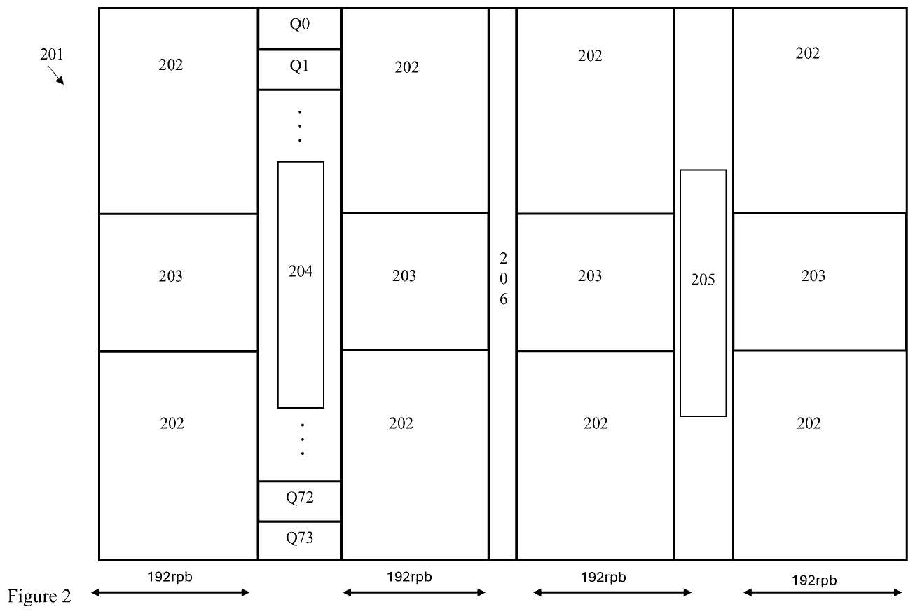

FIG. 2 schematically illustrates a storage circuit according to the conventional technique.

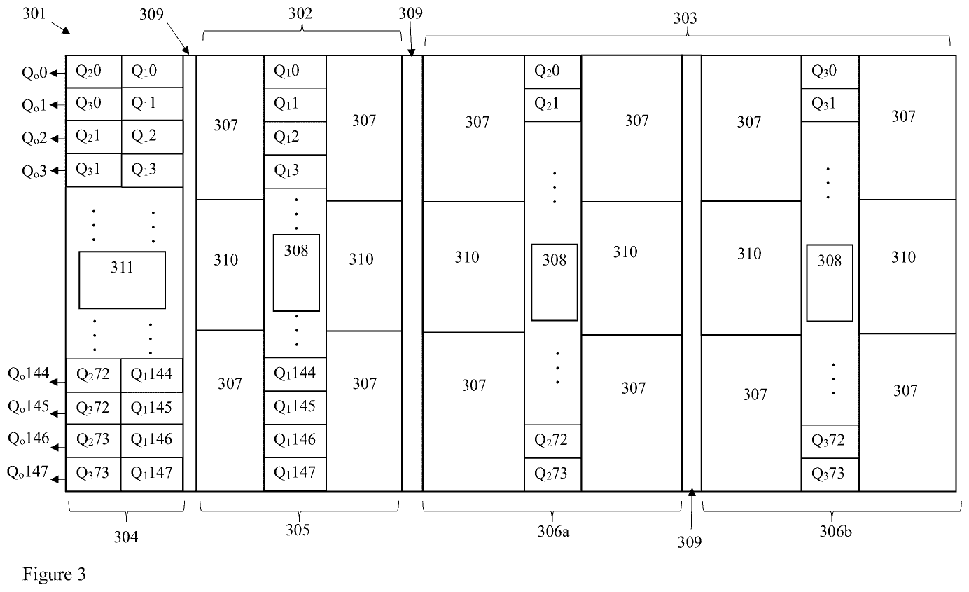

FIG. 3 schematically illustrates a storage circuit according to one or more embodiments of the present disclosure.

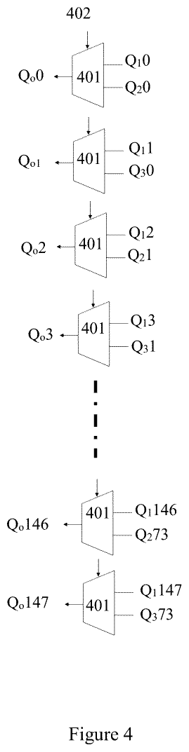

FIG. 4 schematically illustrates a selection circuit according to one or more embodiments of the present disclosure.

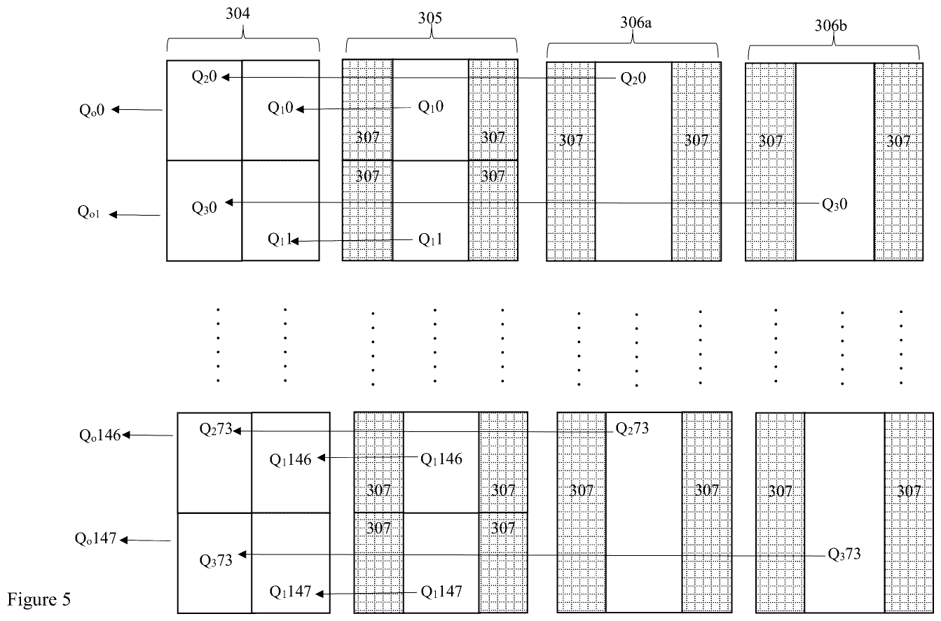

FIG. 5 schematically illustrates a pitch aligned arrangement according to one or more embodiments of the present disclosure.

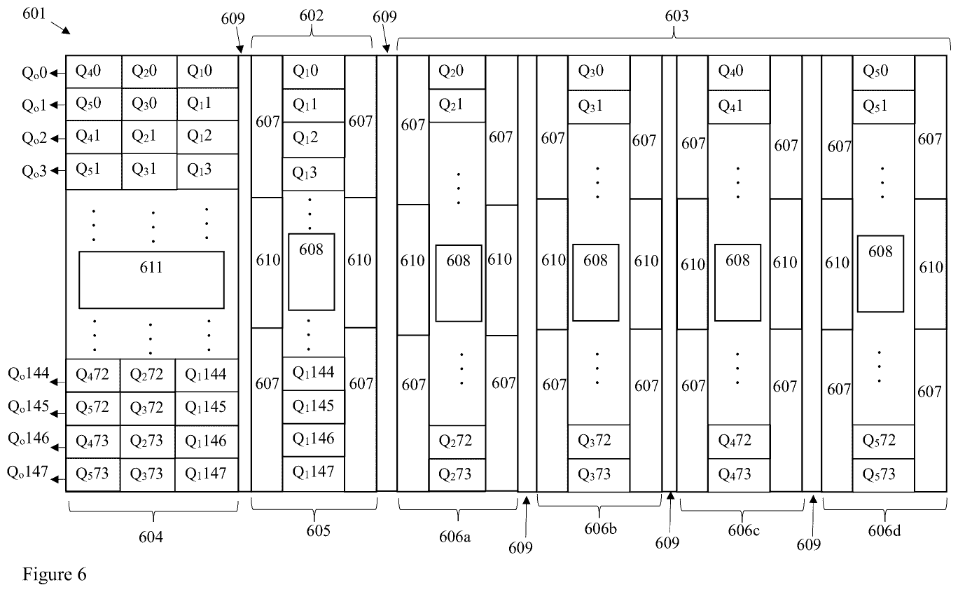

FIG. 6 schematically illustrates a storage circuit according to one or more embodiments of the present disclosure.

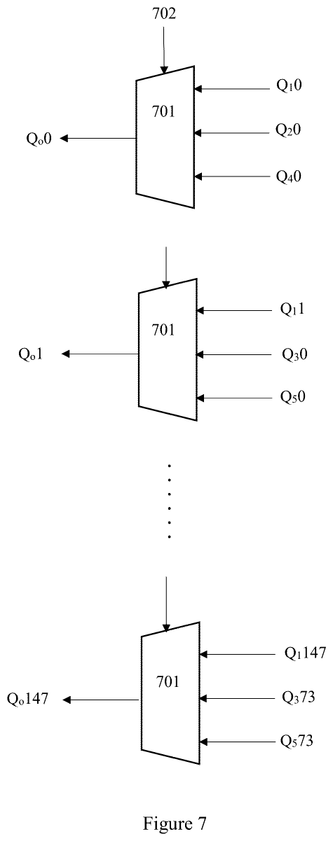

FIG. 7 schematically illustrates a selection circuit according to one or more embodiments of the present disclosure.

### DESCRIPTION

With reference to FIG. 1, which schematically illustrates a storage circuitry 101 (e.g. a memory, or memory circuitry). The storage circuitry 101 may be integrated with computing circuitry and related components on a single chip, and the storage circuitry 101 may be implemented in various embedded systems for automotive, electronic, mobile and Internet-of-things (IoT) applications.

As shown in FIG. 1, the storage circuitry 101 may include core array circuitry 102 having an array of memory cells (or bitcells) arranged in columns and rows. In some embodiments, the storage circuitry 101 may include mux-N (where N maybe 2, 4, 8, 16, etc. depending on the implementation and number of inputs to the multiplexer) core array circuitry, and also, the storage circuitry 101 may refer to mux-N storage circuitry having the core array of memory cells 102 configured to provide column data to the output circuitry 103. In some instances, each memory cell in the core array 102 may be referred to as a bitcell, wherein each bitcell may be configured to store at least one data bit value (e.g., a data value associated with logical ‘0’ or ‘1’). Also, each row of bitcells in the core array 102 may include any number of memory cells arranged in various configurations, such as, e.g., a two-dimensional (2D) core array 102 having columns and rows of bitcells arranged in a 2D grid pattern.

The storage circuitry 101 may include any number of further components and circuitry required in order to implement a functional storage circuit. For example, the storage circuitry may include latch and decoder circuitry, local and global input/output circuitry, control circuitry, transition cells, and so on, which may be separate to, or part of, the core array circuitry 102 within the storage circuitry 101.

In some embodiments, the storage circuitry 101 may refer to memory architecture having the core array circuitry 102 along with output circuitry 103 which includes a number of multiplexer circuitry 104 that is coupled to the core array circuitry 102 via multiple bitlines for read access operations. Thus, the output circuitry 103 may be coupled to the core array circuitry 102, and the output circuitry 103 may include a set of multiplexers 104 (104A, 104B, 104C, 104D) that receives data from the core array 102 of memory cells and provides multiplexed output data (e.g., Q0, Q1, Q2, Q3).

In FIG. 1 there is shown only four multiplexers 104 for ease of description, however, as will be appreciated there may be any number of multiplexers as required for the arrangement implemented and the number of outputs Q.

FIG. 2 schematically illustrates a storage circuit according to a conventional arrangement. In the example of FIG. 2, the logical instance is 4 copy of 6 k×592 , using a storage circuit having a single physical storage circuit 201 of 6 k×74, which can also be considered to be a physical instance. Thus, for each copy of the logical instance 8 copy of the physical instance is required, meaning a total of 32 copy of the physical instance to form the required logical instance of 4 copy of 6 k×592. FIG. 2 shows one physical storage circuit 201 of 6 k×74, having an output of Q0 to Q73.

The physical storage circuit 201 shown in the example of FIG. 2 is implemented using mux8 and Flexible Bank (FB) 4 structure, where FB4 refers to the physical storage circuit 201 having four bitcell banks (where in FIG. 2 each bitcell bank extends vertically above and below the respective latch and decoder circuit 203 of each bitcell bank).

Each bitcell bank 202 has 192 rows per bank (rpb) in the arrangement of FIG. 2, wherein the rpb is typically determined, or calculated, by Words/(mux*bank) in which in the example of FIG. 2 the Words is 6 k (i.e. 6144), mux8 (i.e. 8) is implemented, and the bank is FB4 (i.e. 4), giving 6144/(8*4) which equals 192 rpb. Each bitcell of the bitcell banks 202 being operable to store one bit of data, i.e. a 1 or a 0.

The physical storage circuit 201 may further include additional circuitry and/or components, for example, latch and decoder circuitry 203, a global input/output (I/O) circuitry 204, a local I/O circuitry 205, and a transition cell region 206.

The latch and decoder circuitry 203 includes logic that is operable to latch external input and decoder circuitry to generate Word Line (WL) signal based on an input address, where the WL is an enable signal for bitcell access of the respective bitcell bank, and to generate a signal based on write and read operations.

The Local I/O circuitry 205 is operable to latch input data and transfer the input data to the bitcells for a Write operation. Accordingly, the Local I/O circuitry 205 includes any required circuitry (for example, write driver, read/write pass gate, sense amp latch, and so on) to enable the local I/O to obtain content from any bitcell, based on an address, and transfer the obtained content to the global I/O (e.g. a read operation), and to update the content of any bitcell, based on an address, (e.g. a write operation).

The Global I/O circuitry 204 is similar to the Local I/O circuitry but is further operable to generate, using multiplexers, the final data output Q (Q[0] to Q[n-1], e.g. Q0 to Q73 in the example of FIG. 2) based on the contents of the bitcells and output the data Q to a circuit or component that requires, or requested, the data from the memory (i.e. storage circuitry).

The transition cell region 206 acts as an interference between adjacent bitcell banks and is typically based on guidelines to limit the number of bitcells per rows per bank and to provide sufficient well/tap connection.

As mentioned above, for a logical instance of 4 copy of 6 k×592, then implementing the conventional arrangement would require 32 copies of the physical storage circuit 201 shown in FIG. 2, which is not area efficient.

The Applicants have identified that the conventional arrangement is inefficient, in terms of the physical area of the storage circuitry (i.e. memory) required and routing congestion especially for mobile devices, as the requirements for the size of the logical instance of memory increases. Thus, the Applicants propose a new storage circuitry arrangement that has a greater area efficiency, lower routing congestion, and can be scalable for increasing logical instance size.

FIG. 3 illustrates schematically an arrangement of a storage circuit 301 (e.g. memory) according to one or more embodiments of the present disclosure. As with the example shown in FIG. 2, the logical instance is 4 copy of 6 k×592 , for ease of comparison to the conventional arrangement described above, but, in contrast to FIG. 2, a physical instance of 6 k×148. Thus, 4 copy of the physical instance is required for 1 copy of 6 k×592 and as such, 16 copy of the physical instance is required for the logical instance of 4 copy of 6 k×592.

The storage circuit 301 comprises a first storage circuit instance 302, a second storage circuit instance 303, and a selection circuit 304, wherein the combination of the first storage circuit instance and the second storage circuit instance can be considered to be a physical instance of the storage circuit.

The first storage instance 302 includes a first physical storage circuit 305 and the second storage circuit instance 303 includes one or more pairs of second physical storage circuits 306, wherein one pair of second physical storage circuits 306a, 306b, is required for, and shown, in the example of FIG. 3.

In the example of FIG. 3, the first physical storage circuit 305 is a 2 k×148 mux4 FB2, and each of the second physical storage circuits 306a, 306b of the pair of second physical storage circuits are a 4 k×74 mux8FB2 .

The first and second physical storage circuits include two bitcell banks 307 (where in FIG. 3 each bitcell bank extends vertically above and below the respective latch and decoder circuit 310 of each bitcell bank) having 256 rows per bank (rpb). Each bitcell of the bitcell banks 307 being operable to store one bit of data, i.e. a 1 or a 0.

The number of outputs Q₁ of the first physical storage circuit of the first storage instance 301, being Q₁0 to Q₁147 in the example of FIG. 3, matches the number of outputs Q of the pair of second physical storage circuits of the second storage instance, being Q₂0 to Q₂73 and Q₃0 to Q₃73 respectively in FIG. 3. In other words, the number of outputs of the first physical storage circuit (e.g. 148) matches the combined total number of outputs of the pair of second physical storage circuits (e.g. 74+74). The total number of outputs of the storage circuit Qₒ may match the total number of outputs Q₁ of the first physical storage circuit 305 of the first storage instance 302.

The selection circuit 304 in FIG. 3 includes global I/O circuitry 311 which, based on a control signal, selects, for a given output Qₒ of the storage circuit, an output from the first storage circuit instance (e.g. Q₁) or an output (e.g. Q₂ or Q₃) from the second storage circuit instance.

In embodiments, the selection circuit, for example, the global I/O circuitry, includes a bank mux, wherein the bank mux includes a plurality of multiplexers that are operable to perform bit interleaving between the outputs of the first physical storage circuit of the first storage circuit instance and the outputs of the one or more pairs of second physical storage circuits of the second storage circuit instance. The bank mux may be a 2-to-1, 3-to-1, 4-to-1, and so on bank mux depending on the number of pairs of second physical storage circuits and the first physical storage circuit. Thus, in the example of FIG. 3, there is a first physical storage circuit and one pair of second physical storage circuits meaning that the bank mux in the selection circuit of this example is a 2-to-1 bank mux. A 2-to-1 bank mux includes a number of multiplexers, typically the same number of multiplexers as the total number of outputs of the storage circuit, which receive two selection inputs and are operable to select, based on a control signal, a single output from the received two selection inputs. Thus, a 3-to-1 bank mux includes multiplexers that receive three selection inputs and are operable to select, based on a control signal, a single output from the received three selection inputs, and so on.

For each output of the storage circuit the selection circuit may be operable to perform bit interleaving of an output of the first storage circuit instance and one or more outputs of the second storage circuit instance. In the example of FIG. 3, the selection circuit is operable to perform bit interleaving for each output of the storage circuit by bit interleaving an output of the first physical storage circuit of the first storage circuit instance with an alternating output of the pair of second physical storage circuits of the second storage circuit instance.

This is shown in more detail in FIG. 4 which schematically shows the bit interleaving for the arrangement shown in FIG. 3 between the first storage circuit instance and the second storage circuit instance utilizing a2:1 bank mux that includes a number of multiplexers 401 of the selection circuit. As shown in FIG. 4, the overall output Qₒ0 is selected, based on a control signal 402, by a mux 401 from the two selection inputs being Q₁0 and Q₂0, the overall output Qₒ1 is selected by a mux 401 from the two selection inputs being Q₁1 and Q₃0, the overall output Qₒ2 is selected by a mux 401 from the two selection inputs being Q₁2 and Q₂1, the overall output Qₒ3 is selected by a mux 401 from the two selection inputs being Q₁3 and Q₃2 and so on until through to overall output Qₒ144 which is selected by a mux 401 from the two selection inputs being Q₁144 and Q₂72, the overall output Qₒ145 is selected by a mux 401 from the two selection inputs being Q₁145 and Q₃72, Qₒ146 is selected by a mux 401 from the two selection inputs being Q₁146 and Q₂73, Qₒ147 is selected by a mux 401 from the two selection inputs being Q₁147 and Q₃73.

Thus, the overall output of the storage circuit is selected from the corresponding output of the first storage circuit instance and an alternating output of the second storage circuit instance based on an input control signal to the bank mux.

Returning to FIG. 3, the selection circuit 304 is shown as separate circuitry to the first and second storage circuit instances, for ease of description and for showing the bit interleaving arrangement in FIG. 3. However, other arrangements are of course possible. For example, the selection circuit may be part of, or combined with, the first storage circuit instance (e.g. with the local I/O circuitry of the first physical storage circuit), or part of, or combined with the second storage circuit. In preferred embodiments, the selection circuit is part of, or combined with, the first storage circuit instance to be more area efficient for the storage circuit, as when the selection circuit is separate to the first or second storage instances the storage circuit will typically have a greater area. However, as will be appreciated, the location of the selection circuit will be dependent on the use case of the storage circuit and can be optimised for any given use case.

The storage circuit 301 may further include additional circuitry and/or components, for example, latch and decoder circuitry 310, a local I/O circuitry 308, and a transition cell region 309. However, as will be appreciated, the storage circuit may further include any number of required components or circuitry necessary to implement the storage circuit.

In embodiments, the physical location, or positioning, of the first and second physical storage circuit(s) on a physical chip may be determined to further improve the efficiency. For example, they may be positioned on the physical chip to be pitch-aligned, that is to provide the shortest path interconnects between the local I/O of each physical storage circuit and the corresponding global I/O (i.e. selection circuit). This is shown in FIG. 5, which schematically illustrates the physical storage circuits being pitch aligned between the outputs of each physical storage circuit and the final output of the overall storage circuit. As shown in FIG. 5, the output Qₒ0 of the selection circuit 304 of the storage circuit is pitch aligned with Q₁0 of the first physical storage circuit and Q₂0 of the first of the second physical storage circuits 306a, the output Qₒ1 of the selection circuit 304 of the storage circuit is pitch aligned with Q₁1 of the first physical storage circuit and Q₃0 of the second of the second physical storage circuits 306b, and so on through to output Qₒ146 of the selection circuit 304 of the storage circuit which is pitch aligned with Q₁146 of the first physical storage circuit and Q₂73 of the first of the second physical storage circuits 306a, and output Qₒ147 of the selection circuit 304 of the storage circuit is pitch aligned with Q₁147 of the first physical storage circuit and Q₃73 of the second of the second physical storage circuits 306b.

Thus, by pitch aligning the outputs of the first and second physical storage circuits with the corresponding global, or overall, outputs of the storage circuit advantageously improves the efficiency and reduces the potential for any errors, interference, routing congestion, or other disadvantages caused by none pitch aligned routing of the interconnect paths.

As mentioned above, for a logical instance of 4 copy of 6 k×592, then implementing the arrangement of the embodiments would require 16 copies of the physical instance shown in FIG. 3 in a device. Accordingly, the overall area of the arrangement of the storage circuit of the embodiments provides a significant area advantage over the conventional arrangement as shown in FIG. 2 in which 32 copies of the physical instance of FIG. 2 would be required for the same logical instance.

Thus, in comparison with the conventional arrangement shown in FIG. 2, the arrangement of the present disclosure can provide an area saving of approximately 5%, which is a significant area saving especially in relation to smaller, or mobile, devices where physical footprint is highly important. However, as will be appreciated, depending on the logical instance required, the storage circuit of the embodiments of the present disclosure may provide even greater area efficiency over the conventional arrangements.

As mentioned above, the arrangements of the present disclosure are scalable to larger memory requirements. For example, FIG. 6 schematically illustrates a storage circuit 601 for 1 copy of a logical instance of 10 k×592. The storage circuit 601 comprises a first storage circuit instance 602, a second storage circuit instance 603, and a selection circuit 604, wherein the combination of the first storage circuit instance and the second storage circuit instance can be considered to be a physical instance of the storage circuit.

The first storage instance 602 includes a first physical storage circuit 605 and the second storage circuit instance 603 includes two pairs of second physical storage circuits 606, for example, a first pair being second physical storage circuits 606a and 606b, and a second pair being second physical storage circuits 606c and 606d.

In the example of FIG. 6, the first physical storage circuit 605 is a 2 k×148 mux4 FB2, and each of the second physical storage circuits 606a, 606b, 606c, 606d are a 4 k×74 mux8 FB2.

The first and second physical storage circuits each include two bitcell banks 607 (where in FIG. 6 each bitcell bank extends vertically above and below the respective latch and decoder circuit 610 of each bitcell bank) having 256 rows per bank (rpb). Each bitcell of the bitcell banks 607 being operable to store one bit of data, i.e. a 1 or a 0.

The number of outputs Q₁ of the first physical storage circuit of the first storage instance 602, being Q₁0 to Q₁147 in the example of FIG. 6, matches the number of outputs Q of each of the pairs of second physical storage circuits of the second storage instance. In other words, the number of outputs of the first physical storage circuit (e.g. 148) matches the combined total number of outputs of each pair of second physical storage circuits (e.g. 74+74). The total number of outputs of the storage circuit Qₒ may match the total number of outputs Q₁ of the first physical storage circuit 605 of the first storage instance 602.

The selection circuit 604 in FIG. 6 includes global I/O circuitry 611 which, based on a control signal, selects, for a given output Qₒ of the storage circuit system, an output from the first physical storage circuit of the first storage circuit instance (e.g. Q₁), an output from the first pair of second physical storage circuits (e.g. Q₂ or Q₃), or an output from the second pair of second physical storage circuits (e.g. Q_{4,} or Q₅), from the second storage circuit instance.

In embodiments, the selection circuit, for example, the global I/O circuitry, includes a bank mux, wherein the bank mux includes a plurality of multiplexers that are operable to perform bit interleaving between the outputs of the first physical storage circuit of the first storage circuit instance and the outputs of the one or more pairs of second physical storage circuits of the second storage circuit instance. In the example of FIG. 6, there is a physical storage circuit and two pairs of second physical storage circuits meaning that the bank mux in the selection circuit of this example is a 3:1 bank mux. That is each multiplexer of the 3:1 bank mux receives three selection inputs (e.g. one from the first physical storage circuit, one from the first pair of second physical storage circuits, and one from the second pair of physical storage circuits) and are operable to select, based on a control signal, a single output from the received three selection inputs.

For each output of the storage circuit the selection circuit may be operable to perform bit interleaving of an output of the first storage circuit instance and one or more outputs of the second storage circuit instance. In the example of FIG. 6, the selection circuit is operable to perform bit interleaving for each output of the storage circuit by bit interleaving an output of the first physical storage circuit of the first storage circuit instance with an alternating output of the two pairs of second physical storage circuits of the second storage circuit instance.

This is shown in more detail in FIG. 7 which schematically shows the bit interleaving for the arrangement shown in FIG. 6 between the first storage circuit instance and the second storage circuit instance utilizing the 3:1 bank mux that includes a number of multiplexers 701, based on a control signal 702. As shown in FIG. 7, the overall output Qₒ0 is selected by a mux 701 from the three selection inputs being Q₁0, Q₂0 and Q₄0, the overall output Qₒ1 is selected by a mux 701 from the three selection inputs being Q₁1, Q₃0 and Q₅0, and so on until through to overall output Qₒ147 which is selected by a mux 701 from the three selection inputs being Q₁147, Q₃73 and Q₅73.

Thus, the overall output of the storage circuit is selected from the corresponding output of the first storage circuit instance and an alternating output of the two pairs of physical storage circuits of the second storage circuit instance based on an input control signal to the bank mux.

Returning to FIG. 6, as discussed above, the selection circuit 604 is shown as separate circuitry to the first and second storage circuit instances, for ease of description and for showing the bit interleaving arrangement in FIG. 6. However, as mentioned above, other arrangements are of course possible. For example, the selection circuit may be part of, or combined with, the first storage circuit instance (e.g. with the local I/O circuitry of the first physical storage circuit), or part of, or combined with the second storage circuit. In preferred embodiments, the selection circuit is part of, or combined with, the first storage circuit instance to be more area efficient for the storage circuit, as when the selection circuit is separate to the first or second storage instances the storage circuit will typically have a greater area. However, as will be appreciated, the location of the selection circuit will be dependent on the use case of the storage circuit and can be optimised for any given use case. Further, as discussed above, the outputs of the physical storage circuits may be pitch aligned with the corresponding global, or overall, outputs of the storage circuit.

The storage circuit 601 may further include additional circuitry and/or components, for example, latch and decoder circuitry 610, a local I/O circuitry 608, and a transition cell region 609. However, as will be appreciated, the storage circuit may further include any number of required components or circuitry necessary to implement the storage circuit.

Accordingly, the arrangements and implementations of the present disclosure provide a new and advantageous storage circuit that has greater area efficiency, lower routing congestion, and can be scalable for increasing logical instance size. The storage circuit advantageously includes a first and second storage instance, wherein the second storage instance includes one or more pairs of physical storage circuits, and a selection circuit that is operable to select, for a given output of the storage circuit, an output from the first storage circuit instance or an output from the second storage circuit instance.

As will be appreciated, the specific values provided hereinabove in relation to the described logical instances and the physical instances are merely examples only and the skilled person would appreciate that any values for the logical instances and the physical instances could be used.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

It should be intended that the subject matter of the claims not be limited to the implementations and illustrations provided herein, but include modified forms of those implementations including portions of implementations and combinations of elements of different implementations in accordance with the claims.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

While the foregoing is directed to implementations of various techniques described herein, other and further implementations may be devised in accordance with the disclosure herein, which may be determined by the claims that follow.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A storage circuit comprising:
a first storage circuit instance, wherein the first storage circuit instance comprises a first physical storage circuit;
a second storage circuit instance, wherein the second storage circuit instance comprises one or more pairs of second physical storage circuits; and
a selection circuit, wherein the selection circuit is operable to select, for a given output of the storage circuit, an output from the first storage circuit instance or an output from the second storage circuit instance;
wherein a number of outputs of the first physical storage circuit matches the number of outputs of each of the one or more pairs of second physical storage circuits.

2. The storage circuit of claim 1, in which the selection circuit is part of the first storage circuit instance or the second storage instance.

3. The storage circuit of claim 1, in which the selection circuit is separate to the first storage circuit instance and the second storage circuit instance.

4. The storage circuit of claim 1, in which for each output of the storage circuit the selection circuit is operable to perform bit interleaving of an output of the first storage circuit instance and one or more outputs of the second storage circuit instance.

5. The storage circuit of claim 4, in which the bit interleaving for each output of the storage circuit includes bit interleaving an output of the first physical storage circuit of the first storage circuit instance with an alternating output of one or more pairs of the second physical storage circuits of the second storage circuit instance.

6. The storage circuit of claim 1, in which a physical pitch of the first physical storage circuit and each of the two or more second physical storage circuits are matched.

7. The storage circuit of claim 1, in which the selection circuit receives a control signal;
and the selection is based on the received control signal.

8. The storage circuit of claim 1, in which one of the first physical storage circuit and the two or more second physical storage circuits include a bank multiplexer.

9. The storage circuit of claim 1, in which the selection circuit includes a bank multiplexer.

10. The storage circuit of claim 9, in which the bank multiplexer comprises a plurality of multiplexers, wherein each multiplexer of the bank multiplexer comprises two or more selection inputs.

11. The storage circuit of claim 1, in which each of the first physical storage circuit and the two or more second physical storage circuits include a plurality of bitcell banks, an input/output circuit, and at least one latch and decoder circuit.

12. The storage circuit of claim 1, further comprising:
a transition region located between adjacent physical storage circuits.

13. A method of operating a storage circuit, the storage circuit comprising a first storage circuit instance, wherein the first storage circuit instance comprises a first physical storage circuit; a second storage circuit instance, wherein the second storage circuit instance comprises one or more pairs of second physical storage circuits; wherein a number of outputs of the first physical storage circuit matches the number of outputs of each of the one or more pairs of second physical storage circuits; and a selection circuit, the method comprising:
selecting, by the selection circuit, for a given output of the storage circuit system, an output from the first storage circuit instance or an output from the second storage circuit instance.

14. The method of claim 13, further comprising:
performing, by the selection circuit for each output of the storage circuit system, bit interleaving of an output of the first storage circuit instance and one or more outputs of the second storage circuit instance.

15. The method of claim 14, in which the performing bit interleaving further comprises:
bit interleaving an output of the first physical storage circuit of the first storage circuit instance with an alternating output of the one or more pairs of second physical storage circuits of the second storage circuit instance.

16. The method of claim 13, further comprising:
receiving a control signal; and
wherein the selecting is based on the received control signal.

17. A computer program product comprising computer readable executable code for implementing a method according to claim 13.

18. A device comprising one or more copies of the storage circuit of claim 1.

19. A non-transitory computer-readable medium storing computer-readable code for fabrication of a storage circuit comprising:
a first storage circuit instance, wherein the first storage circuit instance comprises a first physical storage circuit;
a second storage circuit instance, wherein the second storage circuit instance comprises one or more pairs of second physical storage circuits; and
a selection circuit, wherein the selection circuit is operable to select, for a given output of the storage circuit system, an output from the first storage circuit instance or an output from the second storage circuit instance;
wherein a number of outputs of the first physical storage circuit matches a number of outputs of each of the one or more pairs of second physical storage circuits.
